(19) United States
(12) Patent Application Publication
(10) Pub. No.: US 2009/0102472 A1
(43) Pub. Date: Apr. 23, 2009

(54) MAGNETIC SENSOR DEVICE WITH FIELD GENERATORS AND SENSORS

(75) Inventors: Jeroen Hans Nieuwenhuis, Waalre (NL); Hans Zon Van, Waalre (NL); Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/299,704

(22) PCT Filed: May 2, 2007
(86) PCT No.: PCT/IB2007/051640

§ 371 Date: Nov. 5, 2008

(30) Foreign Application Priority Data
May 9, 2006 (EP) 06113710.5

(51) Int. Cl. G01R 33/12

(52) U.S. Cl. 324/228

(57) ABSTRACT

The invention relates to a magnetic sensor device (10) comprising magnetic field generators (11, 13) for generating a magnetic excitation field (B) in an investigation region and a magnetic sensor element (12) for measuring magnetic reactions fields (B′) generated by magnetized particles (2) that are bound to binding sites (3) in the investigation region. Both the magnetic field generators (11, 13) and the magnetic sensor element (12) are driven with electrical power, wherein the ratio of the power that is dissipated in said components is kept in a predetermined interval. The magnetic field generators may preferably be realized by excitation wires (11, 13) and the sensor element (12) by a magneto-resistive element, for example a GMR element. In this case, it is preferred that about equal amounts of power are dissipated in the excitation wires (11, 13) and the GMR element (12).

The invention relates to a magnetic sensor device comprising at least one magnetic field generator, at least one magnetic sensor element, and an associated power supply unit. Moreover, the invention relates to the use of such a magnetic sensor device and to a method for supplying the components of such a sensor device with electrical power.

From the WO 2005/010543 A1 and WO 2005/010542 A2 (which are incorporated into the present application by reference) a magnetic sensor device is known which may for example be used in a microfluidic biosensor for the detection of target molecules, e.g. biological molecules, labeled with magnetic beads. The magnetic sensor device is provided with an array of sensor units comprising wires for the generation of a magnetic field and Giant Magneto Resistances (GMR) for the detection of stray fields generated by magnetized beads. The signal of the GMRs is then indicative of the number of the beads near the sensor. As the concentrations of target molecules that are to be measured with such known magnetic sensor devices are often extremely low, the problem arises that the sensor signal is severely corrupted by noise of different sources.

Based on this situation it was an object of the present invention to provide means for improving the signal-to-noise ratio in magnetic sensor devices of the kind described above.

This objective is achieved by a magnetic sensor device according to claim 1, a method according to claim 2, and a use according to claim 10. Preferred embodiments are disclosed in the dependent claims.

A magnetic sensor device according to the present invention comprises the following components:
a) At least one magnetic field generator for generating a magnetic field in an adjacent investigation region. The magnetic field generator may for example be realized by a wire on a substrate of a microelectronic sensor device.
b) At least one magnetic sensor element that is associated with the aforementioned magnetic field generator in the sense that it is in the reach of effects caused by the magnetic field of the magnetic field generator. The magnetic sensor element is designed to generate a measurement signal indicative of the magnetic field (or at least a component thereof) which prevails at the location of the magnetic sensor element (or a sensitive region thereof), wherein the magnetic sensor elements has to be driven with electrical power for generating said measurement signal.
c) A power supply unit for supplying the magnetic field generator and the magnetic sensor element with the electrical power that they need to fulfill their functions, wherein a part of this supplied electrical power (called the “total dissipated power P” in the following) is dissipated—i.e. converted into heat—in the magnetic field generator and the magnetic sensor element. The power supply unit shall further be designed such that the fraction f of this total dissipated power P which is dissipated in the magnetic sensor element alone is kept in a predetermined interval.

The invention further relates to a method for supplying electrical power to at least one magnetic field generator for generating a magnetic excitation field in an investigation region and to at least one associated magnetic sensor element for generating a measurement signal indicative of the prevailing magnetic field, wherein said magnetic field generator and magnetic sensor element belong to a magnetic sensor device. Furthermore, a total power P is dissipated in the magnetic field generator and the magnetic sensor element, wherein the fraction f of this total dissipated power P which is dissipated in the magnetic sensor element alone is kept in a predetermined interval.

The magnetic sensor device and the method defined above take care of the ratio between the power Pₛₑₙₛₑ dissipated in the magnetic sensor element and the power P_{exc} dissipated in the magnetic field generator, respectively, during the operation of the magnetic sensor device. Practice and theory show that this ratio Pₛₑₙₛₑ:P_{exc} (or, equivalently, the above defined fraction f=Pₛₑₙₛₑ/(Pₛₑₙₛₑ+P_{exc})=Pₛₑₙₛₑ/P) has a crucial influence on the signal-to-noise ratio that can be achieved by the magnetic sensor device during measurements. Keeping said ratio or the fraction f in a predetermined interval will therefore help to improve the signal-to-noise ratio.

In the following, preferred embodiments of the invention are described that apply to both a magnetic sensor device and a method of the kind described above.

In a first preferred embodiment of the invention, the fraction f of the total dissipated power P that is dissipated in the magnetic sensor element alone lies between about 0.1 and about 0.9, preferably between about 0.3 and about 0.7, wherein the fraction f may assume one constant value from said interval or float within the interval during a measurement. Most preferably, the fraction f has a value of about 0.5, which means that approximately equal amounts of power are dissipated in the magnetic sensor element and the magnetic field generator.

According to another preferred embodiment of the invention, the electrical power is supplied to the magnetic sensor element via a sensing current Iₛₑₙₛₑ. In this case, the power Pₛₑₙₛₑ dissipated in the magnetic sensor element can be calculated as the product of the sensing current Iₛₑₙₛₑ to the square and the resistance Rₛₑₙₛₑ of the magnetic sensor element.

In the aforementioned embodiment, the measurement signal generated by the magnetic sensor element is preferably proportional to the sensing current Iₛₑₙₛₑ. This is for example the case if the measurement signal is the voltage drop across a resistive element.

The magnetic sensor element may optionally be realized by a Hall sensor or a magneto-resistive element like a GMR (Giant Magneto Resistance), a TMR (Tunnel Magneto Resistance), or an AMR (Anisotropic Magneto Resistance) element. These realizations comply with the aforementioned two embodiments, i.e. they are driven with an electrical sensing current and generate a measurement signal proportional to said current.

In a similar way, the electrical power for the magnetic field generator may optionally be supplied by an excitation current I_{exc}.

The magnetic field generator may preferably comprise at least one “excitation” wire. In this case, an excitation current I_{exc} flowing through the excitation wire will generate the magnetic excitation field, and the power P_{exc} dissipated in the magnetic field generator can be calculated as the product of the excitation current I_{exc} to the square and the resistance R_{exc} of the excitation wire. The magnetic field generator preferably comprises a plurality of m>1 excitation wires connected in parallel or in series.

The investigation region of the magnetic sensor device preferably comprises binding sites for magnetic particles, for example antibodies that can bind to complementary molecules labeled with magnetic beads. The magnetic particles can then be magnetized by an excitation field generated by the magnetic field generator, wherein the reaction fields generated by the magnetic particles can further be detected by the magnetic sensor element, allowing the qualitative and quantitative detection of the magnetic particles in the investigation region.

The invention further relates to the use of the magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings, in which:

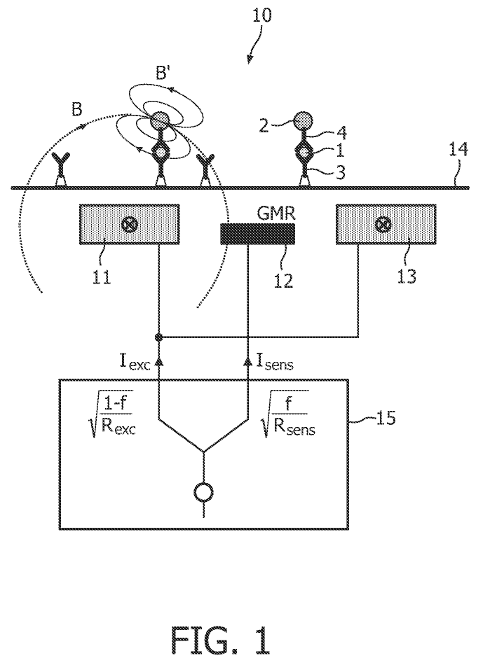

FIG. 1 schematically shows a magnetic sensor device according to the present invention;

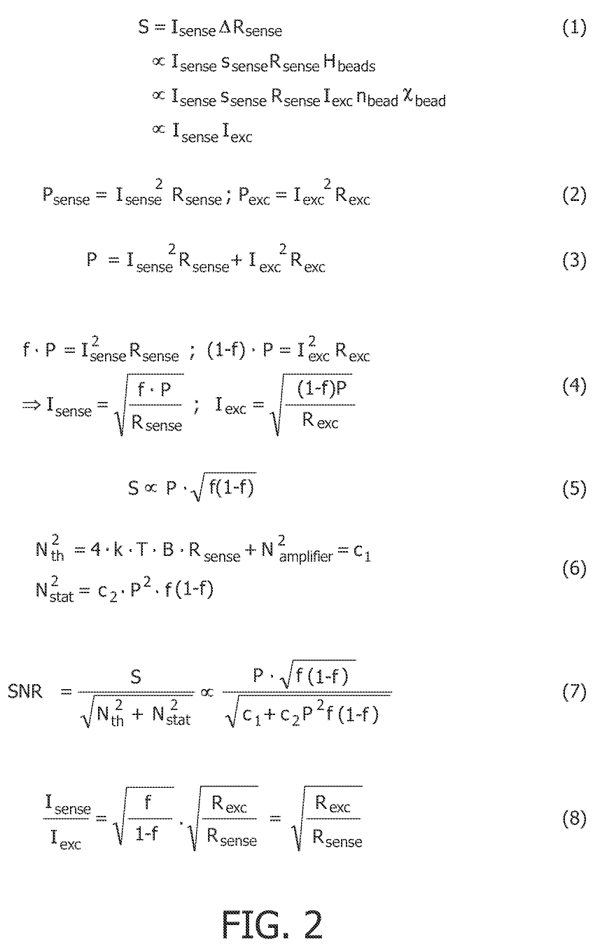

FIG. 2 summarizes different formula relating to the approach of the present invention.

FIG. 1 illustrates the principle of a single sensor 10 for the detection of super-paramagnetic beads 2. A biosensor consisting of an array of (e.g. 100) such sensors 10 may be used to simultaneously measure the concentration of a large number of different target molecules 1 (e.g. protein, DNA, amino acids, drugs) in a solution (e.g. blood or saliva). In one possible example of a binding scheme, the so-called “sandwich assay”, this is achieved by providing a binding surface 14 with first antibodies 3 to which the target molecules 1 may bind. Super-paramagnetic beads 2 carrying second antibodies 4 may then attach to the bound target molecules 1. The super-paramagnetic beads 2 typically consist of a polymer matrix with thousands of magnetic grains. Without an external magnetic field the small magnetic grains inside each bead have a random magnetization such that the magnetic moment of a super-paramagnetic bead is zero. When a super-paramagnetic bead is exposed to a magnetic field, the moments of the magnetic grains inside one bead align, resulting in a magnetic moment for the entire bead.

An excitation current I_{exc} flowing in the excitation wires 11 and 13 of the sensor 10 generates a magnetic field B, which then magnetizes the super-paramagnetic beads 2. Said superparamagnetic beads generate a stray field B′ of which the component in the plane of the GMR element 12 of the sensor 10 causes a magnetization change in the Giant Magneto Resistance (GMR) element which results in a measurable resistance change.

The Figure further shows a power supply unit 15 to which the magnetic excitation wires 11, 13 and the GMR sensor element 12 are coupled (for clarity, the returning electrical leads are not shown in the drawing). Thus the power supply unit 15 can supply the excitation wires 11, 13 with an excitation current I_{exc}, wherein it is assumed that this current is equally divided between the two identically designed excitation wires 11 and 13, respectively. Moreover, the power supply unit 15 supplies the GMR sensor element 12 with a sensing current Iₛₑₙₛₑ, which may be a combination of AC and DC (or solely DC or AC).

Increasing the currents Iₛₑₙₛₑ, I_{exc} through either element improves the SNR, but it also increases the power consumption. Typically the total power dissipation is limited because heating might cause problems (for temperatures above 37 degrees C. activity of certain biochemistry tends to decrease) or because of battery lifetime considerations. The question is therefore how a magnetic biosensor should be operated within a limited power budget to obtain the optimal signal quality. In this respect a method will be described in the following for distributing the power in a magnetic biosensor of the kind described above such that the signal-to-noise ratio (SNR) in the output of the sensor is maximized.

The aforementioned method relies on the fact that by balancing the power dissipation in the sensor element 12 and the accompanying excitation wires 11, 13, the SNR with respect to noise can be increased. This can be explained as follows with reference to the formulas in FIG. 2 (wherein the excitation wires 11 and 13 will be treated as one “excitation element”).

Sending a current through the sensor element 12 and measuring the voltage over the element gives a sensor signal S according to equation (1), wherein Iₛₑₙₛₑ is the current through the sensor element 12, Sₛₑₙₛₑ=(dR/dH)_{H=0}/R is the sensitivity of the sensor element, Rₛₑₙₛₑ is the resistance of the sensor element, I_{exc} is the current through the excitation element 11, 13, n_{bead} is the number of beads on the sensor and Ω_{bead} is the magnetic susceptibility of a single bead.

The power dissipation in the sensor element 12 and the excitation element 11, 13 are given by equation (2), while the total power P dissipated in the biosensor is given be equation (3). It should be noted that R_{exc} is the total resistance of the excitation element, e.g. the parallel resistance of the wires 11, 13 of FIG. 1 (assuming that they are connected in parallel).

A fraction f of this total dissipated power P is dissipated in the magnetic sensor element 12 while a fraction (l-f) is dissipated in the excitation element 11, 13. From this the currents in the sensor and excitation elements can be calculated according to equation (4). The signal S, which is proportional to the product of Iₛₑₙₛₑ and I_{exc}, can then be expressed by equation (5).

The sensor signal will always show some fluctuation, due to various noise sources. These sources can be divided in a) terms which are independent of the used power, such as the various thermal noise factors in the sensor and/or amplifier, Nₜₕ, and b) terms which are dependent of the used power such as terms which include the arrival statistics of the beads and variations in the bead diameter, Nₛₜₐₜ. These noise sources can be written as in equation (6), allowing to express the SNR by equation (7).

The SNR can be optimized with respect to f by solving the equation dSNR/df=0. This yields three solutions: f<0, f=0.5, and f>1. The solutions f<0 and f>1 are not relevant to the system. The solution f=0.5 indicates that under all circumstances the optimum signal-to-noise ratio is obtained if the power is equally divided between the sensor element 12 and the excitation element 11, 13. The noise of the measurements typically originates from two sources, thermal noise from the resistive sensor element 12 and from the electronics, and statistical noise caused by various factors such as bead position and variation in bead diameter. In case the statistical noise is much larger than the thermal noise, the SNR-ratio becomes independent of the power distribution, so f=0.5 does not give a real advantage over other distributions. However, in an optimally designed system the thermal noise is about equal in magnitude to the statistical noise. So, choosing f=0.5 for the system guarantees that under all conditions the maximum SNR is obtained. In practice, a range between f=0.1 and f=0.9 is preferred.

From equation (4) it follows that the ratio between the current Iₛₑₙₛₑ through the sensor element 12 and the current I_{exc} through the excitation element 11, 13 under power balance (f=0.5) can be expressed as in equation (8). Therefore, when the current through one of the elements is changed, the current through the other element should be changed accordingly in order to maintain power balance.

In summary, optimal read-out conditions and an optimal SNR for a magnetic biosensor are achieved if the dissipated power in both the sensor element and the excitation element are equal. This holds true for any type of magnetic biosensor of which the output signal scales with the current through the sensor element, such as GMR, AMR and Hall-type magnetic biosensors.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (10), comprising
a) at least one magnetic field generator (11, 13) for generating a magnetic excitation field (B) in an investigation region;
b) at least one associated magnetic sensor element (12) for generating a measurement signal indicative of a magnetic field (B, B′);
c) a power supply unit (15) for supplying the magnetic field generator (11, 13) and the magnetic sensor element (12) with electrical power, wherein a total power P is dissipated in the magnetic field generator (11, 13) and the magnetic sensor element (12) and wherein the fraction f of this total dissipated power P, which is dissipated in the magnetic sensor element (12) alone, is kept in a predetermined interval.

2. A method for supplying electrical power to at least one magnetic field generator (11, 13) for generating a magnetic excitation field (B) in an investigation region and to at least one associated magnetic sensor element (12) for generating a measurement signal indicative of a magnetic field (B, B′), wherein a total power P is dissipated in the magnetic field generator (11, 13) and the magnetic sensor element (12) and wherein the fraction f of this total dissipated power P, which is dissipated in the magnetic sensor element (12) alone, is kept in a predetermined interval.

3. The magnetic sensor device (10) according to claim 1,
characterized in that said fraction f of the total dissipated power P has a value between 0.1 and 0.9, preferably between 0.3 and 0.7, most preferably a value of about 0.5.

4. The magnetic sensor device (10) according to claim 1,
characterized in that the electrical power is supplied to the magnetic sensor element (12) via a sensing current (Iₛₑₙₛₑ).

5. The magnetic sensor device (10) or the method according to claim 4,
characterized in that the measurement signal generated by the magnetic sensor element (12) is proportional to the sensing current (Iₛₑₙₛₑ).

6. The magnetic sensor device (10) according to claim 1,
characterized in that the magnetic sensor element (12) comprises a Hall sensor or a magneto-resistive element like a GMR (12), an AMR, or a TMR element.

7. The magnetic sensor device (10) according to claim 1,
characterized in that the electrical power is supplied to the magnetic field generator (11, 13) via an excitation current (I_{exc}).

8. The magnetic sensor device (10) according to claim 1,
characterized in that the magnetic field generator comprises at least one excitation wire (11, 13), preferably a plurality of m>1 excitation wires (11, 13) connected in parallel or in series.

9. The magnetic sensor device (10) according to claim 1,
characterized in that the investigation region comprises binding sites (3) for magnetic particles.

10. Use of the magnetic sensor device according to claim 1 for molecular diagnostics, biological sample analysis, and/or chemical sample analysis, particularly the detection of small molecules.
